(19) United States
(12) Patent Application Publication
(10) Pub. No.: US 2026/0194698 A1
(43) Pub. Date: Jul. 9, 2026

(54) MULTI-SPECTRAL OPTICAL FILTER AND METHOD FOR FABRICATING THE SAME

(71) Applicants: LITE-ON SINGAPORE PTE. LTD., Singapore (SG); Singapore University of Technology and Design, Singapore (SG)

(72) Inventors: RUI-TAO ZHENG, Singapore (SG); SIN-HENG LIM, SINGAPORE (SG); WUI-PIN LEE, Singapore (SG); Joel Kwang Wei Yang, Singapore (SG); Md Abdur Rahman, Singapore (SG)

(21) Appl. No.: 19/009,828

(22) Filed: Jan. 3, 2025

(51) Int. Cl. G02B 5/26; G02B 1/10

(52) U.S. Cl. CPC G02B 5/26; G02B 1/10

(57) ABSTRACT

A multi-spectral optical filter and a method for fabricating the same are provided. The multi-spectral optical filter includes a substrate, a first reflection layer, a stepped inorganic layer, and a second reflection layer. The first reflection layer is disposed on the substrate. The stepped inorganic layer is disposed on the first reflection layer, and the stepped inorganic layer includes a first optical film and a second optical film corresponding to a first portion and a second portion of an upper surface of the first reflection layer, respectively. The second reflection layer is disposed on the inorganic layer. Thicknesses of the first optical film and the second optical film are different from each other.

### FIELD OF THE DISCLOSURE

The present disclosure relates to a device and a method for fabricating the same, and more particularly to a multi-spectral optical filter and a method for fabricating the same.

### BACKGROUND OF THE DISCLOSURE

Fabry-Perot (F-P) cavity structures, involving an intermediate dielectric layer sandwiched by two metallic reflectors, have become a promising candidate for multispectral transmission filters due to their superior narrow band full width at half maximum (FWHM). More specifically, colors can be tuned in the F-P cavity structures by controlling the thickness of the intermediate dielectric layer. For example, a greyscale method can be utilized to fabricate the F-P cavity structures.

The greyscale method relies on dose modulation, meaning a single exposure dose is used to create one cavity thickness. Consequently, multiple exposure doses are necessary for fabricating a multispectral filter, resulting in time-consuming and complex processes. As a result, the greyscale method is not scalable for industrial applications due to its intricate procedures and high costs.

Alternatively, Binary lithography and reflow (BLR) can be a better solution than grayscale lithography for creating an array dielectric step with a single exposure dose. However, the BLR method can only be used on e-beam resist, resulting in low thermal stability.

### SUMMARY OF THE DISCLOSURE

In response to the above-referenced technical inadequacies, the present disclosure provides a multi-spectral optical filter and a method for fabricating the same capable of reducing the complexity of the manufacturing process and are compatible with complementary metal-oxide-semiconductor (CMOS) processes.

In order to solve the above-mentioned problems, one of the technical aspects adopted by the present disclosure is to provide a method for fabricating a multi-spectral optical filter, and the method includes the following processes: providing a substrate; disposing a first reflection layer on the substrate; disposing a mask layer on the first reflection layer, in which the mask layer exposes a first portion and a second portion an upper surface of the first reflection layer, respectively; disposing an inorganic layer on the mask layer; disposing a sacrificial layer on the organic layer; patterning the sacrificial layer to form a plurality of first sacrificial structures corresponding to the first portion and a plurality of second sacrificial structures corresponding to the second portion; reflowing the patterned sacrificial layer to form a stepped sacrificial layer, in which the stepped sacrificial layer includes a first sacrificial film formed by the plurality of first sacrificial structures and a second sacrificial film formed by the plurality of second sacrificial structures; performing a pattern transferring process on the stepped sacrificial layer and the inorganic layer to form a stepped inorganic layer, in which the stepped inorganic layer includes a first optical film corresponding to the first portion and a second optical film corresponding to the second portion; and disposing a second reflection layer on the stepped inorganic layer.

In order to solve the above-mentioned problems, another one of the technical aspects adopted by the present disclosure is to provide a multi-spectral optical filter, which includes a substrate, a first reflection layer, a stepped inorganic layer, a second reflection layer and a spacing structure. The first reflection layer is disposed on the substrate. The stepped inorganic layer disposed on the first reflection layer, wherein the stepped inorganic layer includes a first optical film and a second optical film corresponding to a first portion and a second portion of an upper surface of the first reflection layer, respectively. The second reflection layer disposed on the stepped inorganic layer. The spacing structure formed on a third portion of the upper surface of the first reflection layer, wherein the third portion is located between the first portion and the second portion. Thicknesses of the first optical film and the second optical film are different from each other.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for fabricating a multi-spectral optical filter according to one embodiment of the present disclosure;

FIGS. 2 to 10 are schematic views of steps S101 to S109 of the method for fabricating a multi-spectral optical filter according to one embodiment of the present disclosure;

FIG. 11 is a schematic view of a multi-spectral optical filter according to one embodiment of the present disclosure;

FIGS. 12-16 are another schematic view of steps S105-S109 of the method for fabricating a multi-spectral optical filter according to one embodiment of the present disclosure;

FIG. 17 is a schematic view of a multi-spectral optical filter according to another one embodiment of the present disclosure;

FIG. 18 is a schematic view of a multi-spectral optical filter according to yet another one embodiment of the present disclosure;

FIGS. 19 and 20 are scanning electron microscope images each showing a patterned sacrificial layer that includes multiple sacrificial structures according to one embodiment of the present disclosure; and

FIGS. 21 to 23 show reflectance spectral of the multi-spectral optical filter with three channels fabricated by using the method of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

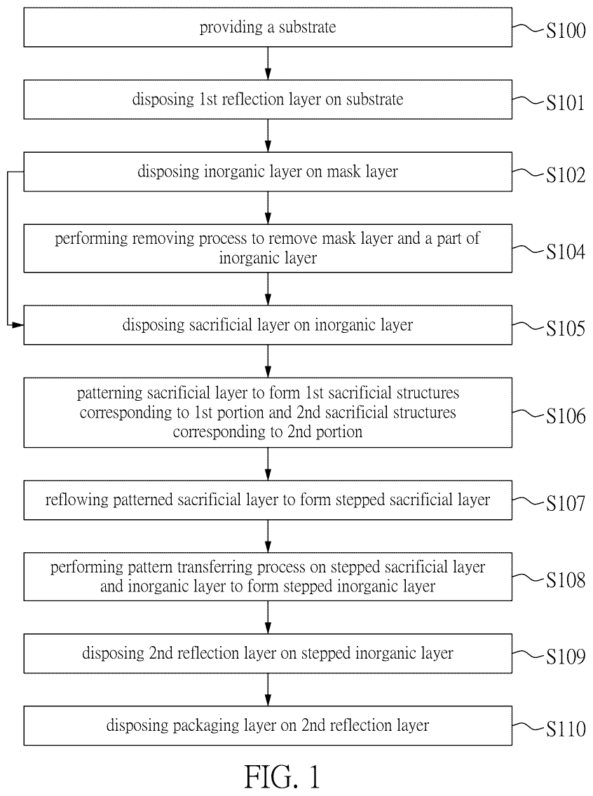

Referring to FIG. 1, one embodiment of the present disclosure provides a method for fabricating a multi-spectral optical filter, the method includes the following processes:

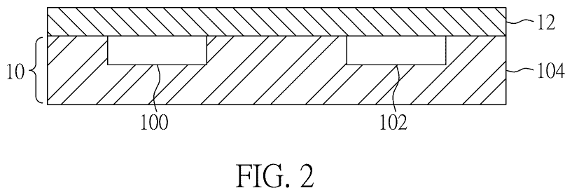

Step S100: providing a substrate. As shown in FIG. 2, the substrate 10 can includes a first sensor 100, a second sensor 102 and a base layer 104. The base layer 104 can be made of silicon oxide, and each of the first sensor 100 and the second sensor 102 can be a photodiode, but the present disclosure is not limited thereto.

Step S101: disposing a first reflection layer on the substrate. As shown in FIG. 2, the first reflection layer 12 can be made of silver (Ag) and serve as one metallic reflector of a Fabry-Perot (F-P) cavity structure.

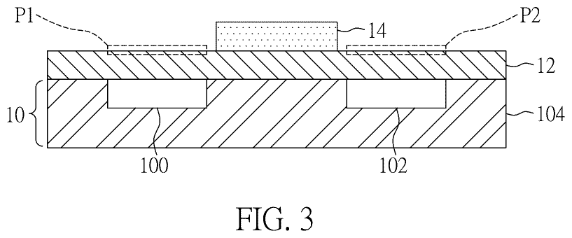

Step S102: disposing a mask layer on the first reflection layer. Referring to FIG. 3, in step S102, the mask layer 14 can be made of black matrix resist, which can expose a first portion P1 and a second portion P2 of an upper surface of the first reflection layer 12, respectively. More specifically, the mask layer 14 is disposed on a third portion P3 of the upper surface of the first reflection layer 12, and the third portion P3 is located between the first portion P1 and the second portion P2. Furthermore, the first portion P1 and the second portion P2 can be located at positions corresponding to positions where the first sensor 100 and the second sensor 102 are disposed, or the first portion P1 and the second portion P2 can be at positions where projections of the first sensor 100 and the second sensor 102 are formed onto the he upper surface of the first reflection layer 12.

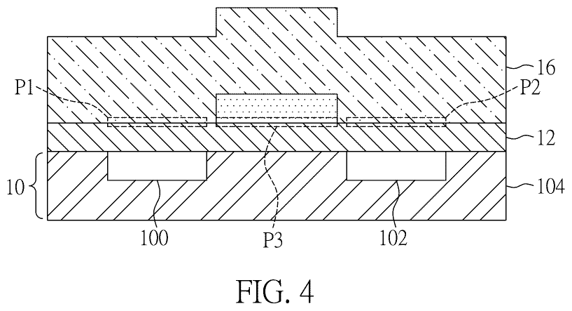

Step S103: disposing an inorganic layer on the mask layer. As shown in FIG. 4, the inorganic layer 16 can be made of silicon dioxide as major optical filter layer and covers the mask layer 14, the first portion P1 and the second portion P2. The inorganic layer 16 has a protrusion portion corresponding to the mask layer 14.

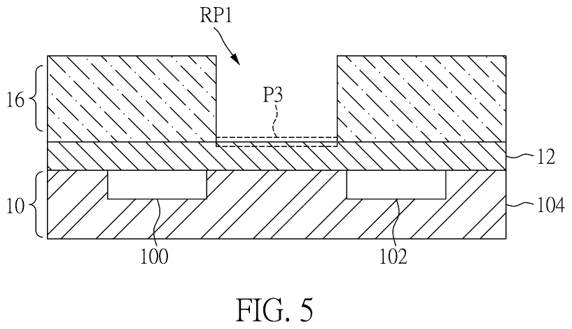

Step S104: performing a removing process to remove the mask layer and a part of the inorganic layer. As shown in FIG. 5, in step S104, a recess portion RP1 is formed in the inorganic layer 16 to expose the third portion P3 after the mask layer 14 is removed.

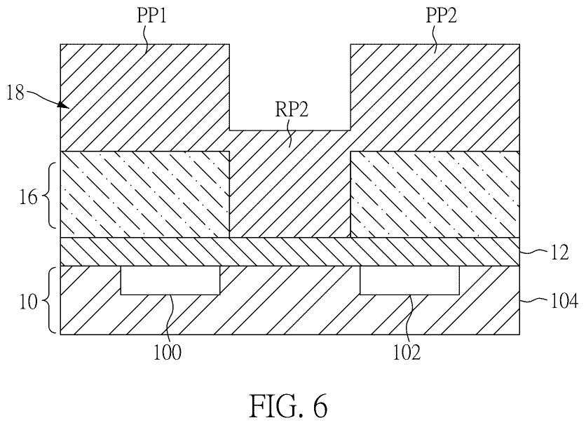

Step S105: disposing a sacrificial layer on the inorganic layer. As shown in FIG. 6, in step S105, the sacrificial layer 18 can be formed on the inorganic layer 16 by filling the recess portion RP1, and a first protrusion portion PP1, a second protrusion portion PP2 and a recess portion RP2 are formed in the sacrificial layer 18. It should be noted that the first protrusion portion PP1, the second protrusion portion PP2 and the recess portion RP2 can be formed by dielectric layers made of polymethyl methacrylate (PMMA). More specifically, PMMA can be spin-coated on the inorganic layer 16, and the first protrusion portion PP1, the second protrusion portion PP2 and the recess portion RP2 can be formed after PMMA stands still and reaches a stable state.

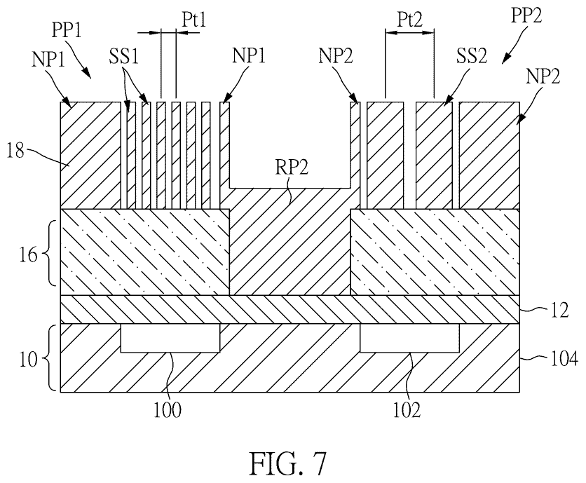

Step S106: patterning the sacrificial layer to form a plurality of first sacrificial structures and a plurality of second sacrificial structures. As shown in FIG. 7, the first sacrificial structures SS1 and the second sacrificial structures SS2 can be formed by performing an electron beam lithography (EBL) process on the sacrificial layer 18, so as to form a plurality of nano-patterned structures that are developed within the first protrusion portion PP1 and the second protrusion portion PP2 respectively corresponding to the first portion P1 and the second portion P2. The first sacrificial structures SS1 are separately arranged by a first pitch Pt1, and the second sacrificial structures SS2 are separately arranged by a second pitch Pt2. The first pitch Pt1 and the second pitch Pt2 are different from each other, but the present disclosure is not limited thereto. Each of the first sacrificial structures SS1 and the second sacrificial structures SS2 can be a nano-column or a nano-pillar having a rectangular-shaped or circular-shaped cross-section.

In certain embodiments, the first pitch Pt1 and the second pitch Pt2 can be the same, but the first sacrificial structures SS1 and the second sacrificial structures SS2 differ from one another at least one in one or more of shape, size and quantity. In other cases, the first sacrificial structures SS1 and the second sacrificial structures SS2 are different in an area ratio, for example, an area ratio of cross-sectional areas of the sacrificial structures in a top view to a total area of the protrusion portion.

In other embodiments, each of the first sacrificial structures SS1 and the second sacrificial structures SS2 can be a nano-hole formed in the patterned sacrificial layer 18, the first sacrificial structures SS1 can be separately arranged by a first hole width, and the second sacrificial structures SS2 can be separately arranged by a second hole width different from the first hole width.

Furthermore, a first non-patterned portion NP1 can be formed to surround the first sacrificial structures SS1, and a second non-patterned portion NP2 can be formed to surround the second sacrificial structures SS2.

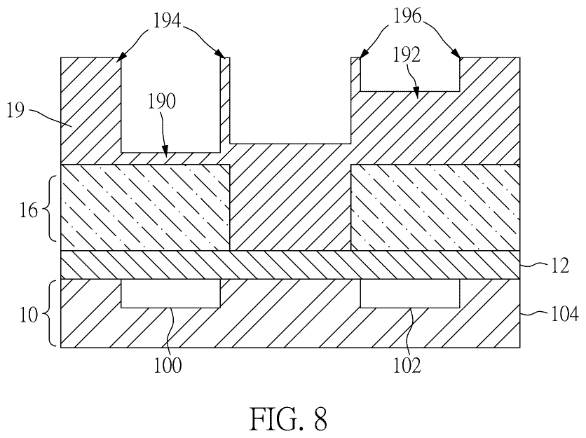

Step S107: reflowing the patterned sacrificial layer to form a stepped sacrificial layer. As shown in FIGS. 7 and 8, in step S106 and S17, binary lithography and reflow (BLR) processes can be performed in sequence, so as to obtain the stepped sacrificial layer 19 with a first sacrificial film 190 and a second sacrificial film 192 having precisely-controlled thicknesses. Specifically, after the thermal reflow process is performed on the patterned sacrificial layer 18 (e.g., 160° C. to 200° C. for few minutes), the first sacrificial film 190 corresponding to the first portion is formed from the first sacrificial structures SS1 and the second sacrificial film 192 corresponding to the second portion is formed from the second sacrificial structures SS2.

Since the first pitch Pt1 is different from the second pitch Pt2, thicknesses of the first sacrificial film 190 and the second sacrificial film 192 can be precisely controlled to be different from each other, which affects structural characteristics of an optical film formed after step S107.

Furthermore, a first boundary 194 is formed by the first non-patterned portion NP1 and surrounds the first sacrificial film 190, and a second boundary 196 is formed by the second non-patterned portion NP2 and surrounds the second sacrificial film 192. A thickness of the first boundary 194 and a thickness of the second boundary 196 can be larger than the thickness of the first sacrificial film 190 and the thickness of the second sacrificial film 192.

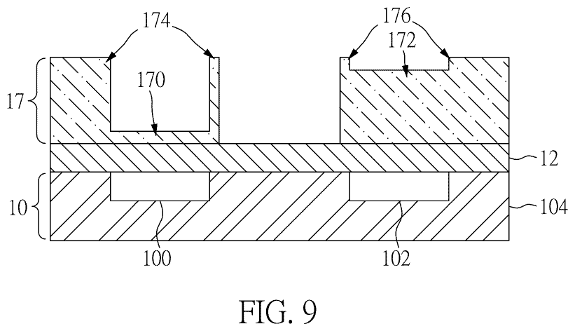

Step S108: performing a pattern transferring process on the stepped sacrificial layer and the inorganic layer to form a stepped inorganic layer. As shown in FIG. 9, the stepped inorganic layer 17 can be formed by performing an inductively coupled plasma etching (ICP RIE) process on the profile of the stepped sacrificial layer 19 and the inorganic layer 16, during which CF₄ plasma can be used.

The stepped inorganic layer 17 includes a first optical film 170 corresponding to the first portion P1 and a second optical film 172 corresponding to the second portion P2. Since the thicknesses of the first sacrificial film 190 and the second sacrificial film 192 are different from each other, thicknesses of the first optical film 170 and the second optical film 172 are also different from each other. The stepped inorganic layer 17 also includes a first boundary 174 surrounding the first optical film 170 and a second boundary 176 surrounding the second optical film 172. Furthermore, heights of tops of the first boundary 174 and the second boundary 176 are larger than heights of tops of the first optical film 170 and the second optical film 172.

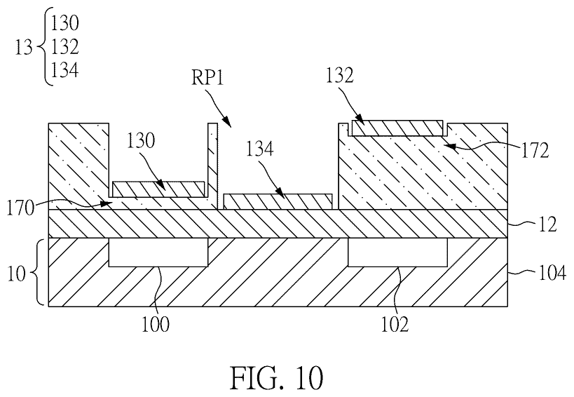

Step S109: disposing a second reflection layer on the stepped inorganic layer. Referring to FIG. 10, the second reflection layer 13 includes a first reflection film 130, a second reflection film 132 and a third reflection film 134 respectively corresponding to the first portion P1, the second portion P2 and the third portion P3 of the upper surface of the first reflection layer 12. More specifically, the first reflection film 130 is formed on the first optical film 170, the second reflection film 132 is formed on the second optical film 172, and the third reflection film 134 is formed on the third portion P3 of the first reflection layer 12 while filling a part of the recess portion RP1. Furthermore, the stepped inorganic layer 17 has two accommodation spaces, one of which is formed by the first optical film 170 and the first boundary 174 and provides a space to contain the first reflection film 130 and another one of which is formed by the second optical film 172 and the second boundary 176 and provides another space to contain the second reflection film 132. Since the thicknesses of the first optical film 170 and the second optical film 172 are different form each other, heights of the first reflection film 130, the second reflection film 132 and the third reflection film 134 are different from one another. The second reflection layer 13 can be made of silver (Ag) and serve as another one metallic reflector of the F-P cavity structure.

Step S110: disposing a packaging layer on the second reflection layer.

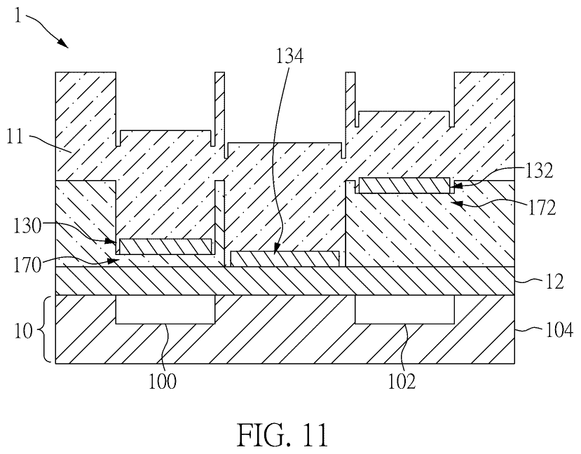

Referring to FIG. 11, a multi-spectral optical filter 1 is completed. The packaging layer 11 can be made of SiO₂ and formed to cover the second reflection layer 13 and the stepped inorganic layer 17, so as to serve as a protection layer of the multi-spectral optical filter 1. It should be noted that the packaging layer 11, the first optical film 170 and the second optical film 172 can be made of identical materials, such as SiO₂. The multi-spectral optical filter 1 includes two F-P cavity structures, one of which is formed of the first reflection layer 12, the first optical film 170 and the first reflection film 130, and another F-P cavity structure is formed of the first reflection layer 12, the second optical film 172 and the second reflection film 132. The two F-P cavity structures have a spacing structure formed therebetween, which is stacked by the first reflection layer 12 and the third reflection film 134 of the second reflection layer 13 for reducing cross-talk effect between different F-P cavity structures. In other words, the spacing structure surrounds any one of the two F-P cavity structures.

It should be noted that, in certain embodiments, a transmission efficiency and a spectral resolution of the multi-spectral optical filter 1 can be further increased by replacing the first reflection layer 12 and the second reflection layer with distributed bragg reflectors (DBR). Moreover, although the multi-spectral optical filter 1 merely includes two F-P cavity structures (two channels), the present disclosure is not limited thereto, the multi-spectral optical filter 1 can further include three or more F-P cavity structures by forming the inorganic layer with a corresponding quantity of optical films having different thicknesses.

That is, the multi-spectral optical filter 1 having multiple channels can be fabricated by precisely controlling the thicknesses of the optical films (e.g., 170 and 172). The method provided by the present disclosure is CMOS compatible and capable of avoiding multiple coating processes to be performed for each channel, while achieving multiple spectra through the BLR process followed by transferring patterns onto the dielectric layer.

Compared with the existing processes, the multi-spectral optical filter 1 and the method for fabricating the same provided by the present disclosure is more robust as well as reducing the complexity of the manufacturing process, allowing the number of mask steps to be substantially reduced.

Referring to FIG. 1 again, in another embodiment, step S104 can be omitted to reserve the mask layer 14 as a part of the spacing structure for reducing cross-talk effect between the two F-P cavity structures effectively.

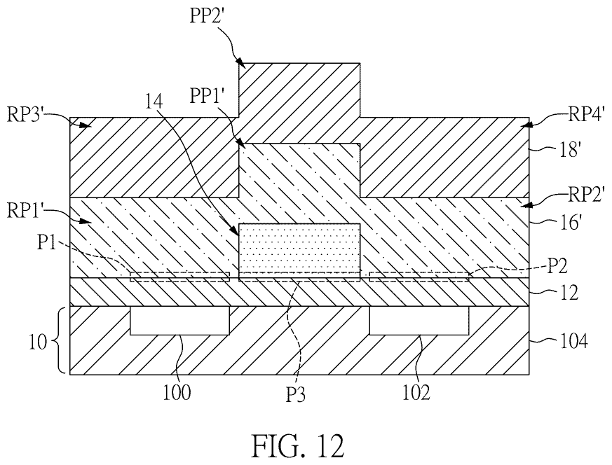

Therefore, after step S103, step S105 is performed to dispose the sacrificial layer 18′ on the inorganic layer 16′. Referring to FIG. 12, the inorganic layer 16′ includes a first protrusion portion PP1′, a first recess portion RP1′ and a second recess portion RP2′. The first protrusion portion PP1′ is formed on the mask layer 14 that is corresponding to the third portion P3 of the upper surface of the first reflection layer 12. The first recess portion RP1′ and the second recess portion RP2′ are formed on the first portion P1 and the second portion P2 of the upper surface of the first reflection layer 12.

Similar to the previous embodiment, the sacrificial layer 18′ can be made of PMMA and spin-coated on the inorganic layer 16′. The second protrusion portion PP2′, a third recess portion RP3′ and a fourth recess portion RP4′ are formed in the sacrificial layer 18′ after PMMA stands still and reaches a stable state.

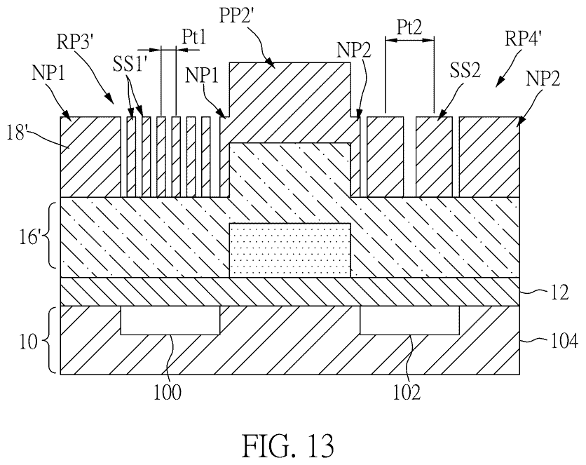

After step S105, step S106 is performed to pattern the sacrificial layer 18′ to form a plurality of first sacrificial structures SS1′ corresponding to the first portion P1 and a plurality of second sacrificial structures SS2′ corresponding to the second portion P2. As shown in FIG. 13, the first sacrificial structures SS1′ and the second sacrificial structures SS2′ can be formed by performing the EBL process on the patterned sacrificial layer 18′, so as to form a plurality of nano-patterned structures that are developed within the third recess portion RP3′ and the forth recess portion RP4′ respectively corresponding to the first portion P1 and the first portion P2. The first sacrificial structures SS1′ are separately arranged by a first pitch Pt1, and the second sacrificial structures SS2′ are separately arranged by a second pitch Pt2. The first pitch Pt1′ and the second pitch Pt2′ are different from each other, but the present disclosure is not limited thereto. Each of the first sacrificial structures SS1′ and the second sacrificial structures SS2′ can be a nano-column, a nano-pillar, and/or nano-wall, and having a rectangular-shaped or circular-shaped cross-section.

In certain embodiments, the first pitch Pt1 and the second pitch Pt2 can be the same, but the first sacrificial structures SS1′ and the second sacrificial structures SS2′ differ from one another at least one in one or more of shape, size and quantity. In other cases, the first sacrificial structures SS1′ and the second sacrificial structures SS2′ are different in an area ratio, for example, an area ratio of cross-sectional areas of the sacrificial structures in a top view to a total area of the protrusion portion.

In other embodiments, each of the first sacrificial structures SS1′ and the second sacrificial structures SS2′ can be a nano-hole formed in the patterned sacrificial layer 18′, the first sacrificial structures SS1′ can be separately arranged by a first hole width, and the second sacrificial structures SS2′ can be separately arranged by a second hole width different from the first hole width.

Furthermore, a first non-patterned portion NP1′ can be formed to surround the first sacrificial structures SS1′, and a second non-patterned portion NP2′ can be formed to surround the second sacrificial structures SS2′.

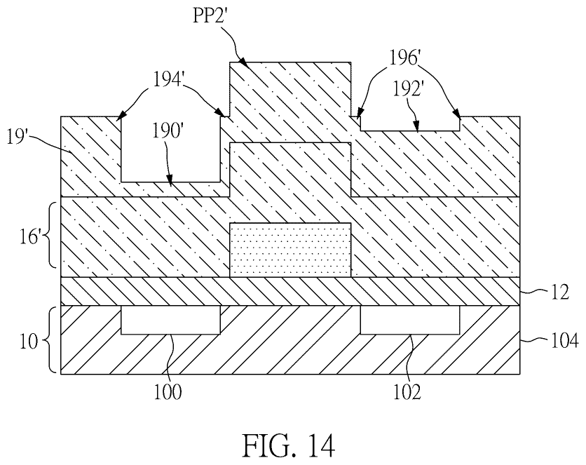

In step S107, the sacrificial layer 16′ is patterned to form a stepped sacrificial layer 19′. As shown in FIGS. 13 and 14, in step S106 and S107, the BLR processes can be performed in sequence, so as to obtain the stepped sacrificial layer 19′ with a first sacrificial film 190′ and a second sacrificial film 192′ having precisely-controlled thicknesses. Specifically, after the thermal reflow process is performed on the patterned sacrificial layer 18′ (e.g., 160° C. to 200° C. for few minutes), the stepped sacrificial layer 19′ can be formed and include the first sacrificial film 190′ formed from the first sacrificial structures SS1′ and the second sacrificial film 192′ formed from the second sacrificial structures SS2′.

Since the first pitch Pt1 is different from the second pitch Pt2, thicknesses of the first sacrificial film 190′ and the second sacrificial film 192′ can be precisely controlled to be different from each other, which affects structural characteristics of an optical film formed after step S107.

Furthermore, a first boundary 194′ is formed by the first non-patterned portion NP1 and surrounds the first sacrificial film 190′, and a second boundary 196′ is formed by the second non-patterned portion NP2 and surrounds the second sacrificial film 192′. a thickness of the first boundary 194′ and a thickness of the second boundary 196′ can be larger than the thickness of the first sacrificial film 190′ and the thickness of the second sacrificial film 192′.

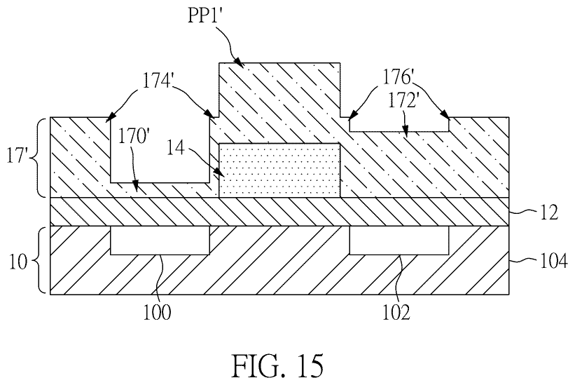

After step S107, a pattern transferring process is performed on the stepped sacrificial layer 19′ and the inorganic layer 16′ in step S108, so as to form a stepped inorganic layer 17′. As shown in FIG. 15, the stepped inorganic layer 17′ can be formed by performing the ICP RIE process on the profile of the stepped sacrificial layer 19′ and the inorganic layer 16′, during which CF₄ plasma can be used. It should be noted that another RIE process using O₂ plasma can be performed to remove a residue of the stepped sacrificial layer 19 (i.e., PMMA), so as to obtained the stepped sacrificial layer 19′ with a cleaned surface.

Referring to FIG. 15, the stepped inorganic layer 17′ includes a first optical film 170′ corresponding to the first portion P1, a second optical film 172′ corresponding to the second portion P2, and the protrusion portion PP1′ reserved from the inorganic layer 16′. Since the thicknesses of the first sacrificial film 190′ and the second sacrificial film 192′ are different from each other, thicknesses of the first optical film 170′ and the second optical film 172′ are also different from each other. The stepped inorganic layer 17′ also includes a first boundary 174′ surrounding the first optical film 170′ and a second boundary 176′ surrounding the second optical film 172′. Furthermore, heights of tops of the first boundary 174′ and the second boundary 176′ are larger than heights of tops of the first optical film 170′ and the second optical film 172′.

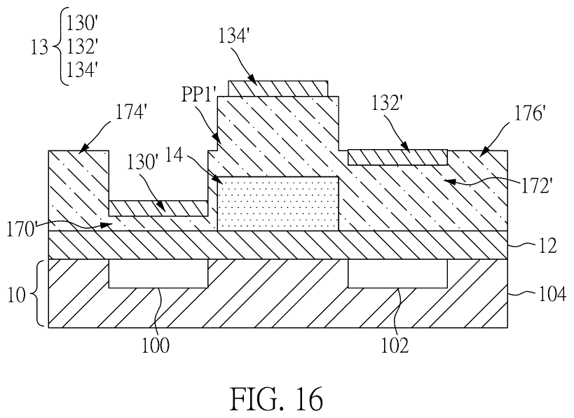

After step S108, step S109 is performed to dispose the second reflection layer 13′ on the stepped inorganic layer 17′. Referring to FIG. 16, the second reflection layer 13′ includes a first reflection film 130′, a second reflection film 132′ and a third reflection film 134′ respectively corresponding to the first portion P1′, the second portion P2′ and the third portion P3′ of the upper surface of the first reflection layer 12. More specifically, the first reflection film 130′ is formed on the first optical film 170′, the second reflection film 132′ is formed on the second optical film 172′, and the third reflection film 134 is formed on the first protrusion portion PP1′. Since the thicknesses of the first optical film 170′ and the second optical film 172′ are different form each other, heights of the first reflection film 130′, the second reflection film 132′ and the third reflection film 134′ are different from one another. The second reflection layer 13′ can be made of silver (Ag) and serve as another one metallic reflector of the F-P cavity structure.

After S109, step S110 is performed to dispose a packaging layer 11′ on the second reflection layer 13.

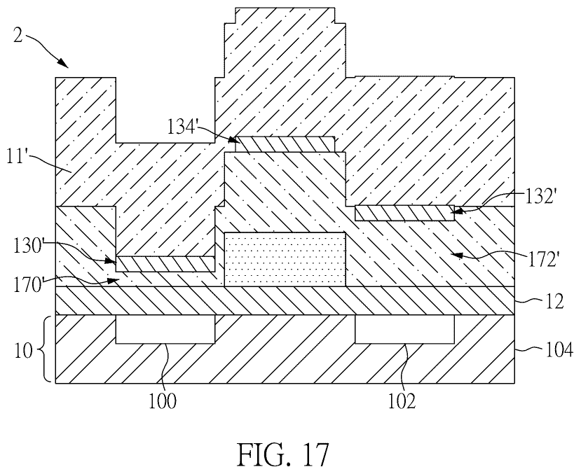

Referring to FIG. 17, a multi-spectral optical filter 2 is completed. The packaging layer 11′ can be made of SiO₂ and formed to cover the second reflection layer 13′ and the stepped inorganic layer 17′, so as to serve as a protection layer of the multi-spectral optical filter 2. It should be noted that the packaging layer 11′, the first optical film 170′ and the second optical film 172′ can be made of identical materials, such as SiO₂. The multi-spectral optical filter 2 includes two F-P cavity structures, one of which is formed of the first reflection layer 12, the first optical film 170′ and the first reflection film 130′, and another F-P cavity structure is formed of the first reflection layer 12, the second optical film 172′ and the second reflection film 132′. The two F-P cavity structures have a spacing structure formed therebetween, which is stacked by the first reflection layer 12, the mask layer 14, the first protrusion portion PP1′ and the third reflection film 134′ for reducing cross-talk effect between different F-P cavity structures. In other words, the spacing structure surrounds any one of the two F-P cavity structures. In some embodiment, an opaque component can be further disposed on the third portion of the upper surface of the first reflection layer 12, and the opaque component can be formed by a light blocking material (e.g., mask layer) or a light reflecting material(e.g., third reflection film). Therefore, the spacing structure in this case can be formed by one or more of the opaque component, the stepped inorganic layer 17′ and the second reflection layer 13′. For example, the stepped inorganic layer 17′ can be a structure formed by the second reflection layer 13′, a structure formed by the opaque component, the stepped inorganic layer 17′ and the second reflection layer 13′, or a structure formed by the opaque component and the stepped inorganic layer 17′. To avoid crosstalk, a distance between two adjacent F-P cavity structures can be less than a width of each F-P cavity structure, such as half of the width of the F-P cavity structure, or preferably be 2 to 3 mm.

It should be noted that, in certain embodiments, a transmission efficiency and a spectral resolution of the multi-spectral optical filter 2 can be further increased by replacing the first reflection layer 12 and the second reflection layer 13′ with DBRs. In addition, the first reflection layer 12 and the second reflection layer 13′ can be optional selected form metal mirror and DBRs. For example, top silver mirror, bottom highly reflective distributed Bragg reflectors (DBRs). Moreover, although the multi-spectral optical filter 2 merely includes two F-P cavity structures (two channels), the present disclosure is not limited thereto, the multi-spectral optical filter 2 can further include three or more F-P cavity structures by forming the inorganic layer with a corresponding quantity of optical films having different thicknesses.

That is, the multi-spectral optical filter 2 having multiple channels can be fabricated by precisely controlling the thicknesses of the optical films (e.g., 170′ and 172′). The method provided by the present disclosure is CMOS compatible and capable of avoiding multiple coating processes to be performed for each channel, while achieving multiple spectra through the BLR process followed by transferring patterns onto the dielectric layer.

Compared with the existing processes, the multi-spectral optical filter 1 and the method for fabricating the same provided by the present disclosure is more robust as well as reducing the complexity of the manufacturing process, allowing the number of mask steps to be substantially reduced.

Furthermore, since the mask layer 14 is not removed, the mask layer 14 located between two different F-P cavity structures can be further used to prevent cross-talk issues.

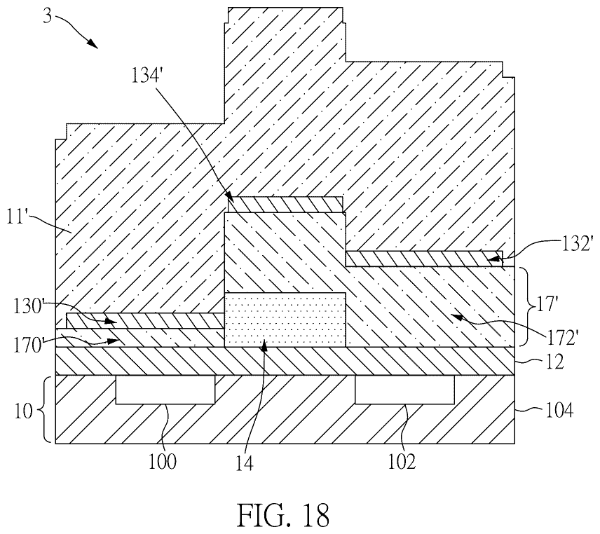

Referring to FIG. 18, in step S106, the first non-patterned portion NP1′ and the second non-patterned portion NP2′ can be omitted. Therefore, in step S107, the third sacrificial film 194′ and the fourth sacrificial film 196′ will not be formed compared to FIG. 14. Furthermore, for the stepped inorganic layer 17″ formed in step S108, the third optical film 174′ and the fourth optical film 176′ will not be formed compared to FIG. 15. As can be seen in FIG. 18, the multi-spectral optical filter 3 can be provided without the third optical film 174′ and the fourth optical film 176′. Furthermore, the first optical film 130′ and the second optical film 132′ are surrounded by the packaging layer 11′ and the stepped inorganic layer 17′ without being exposed.

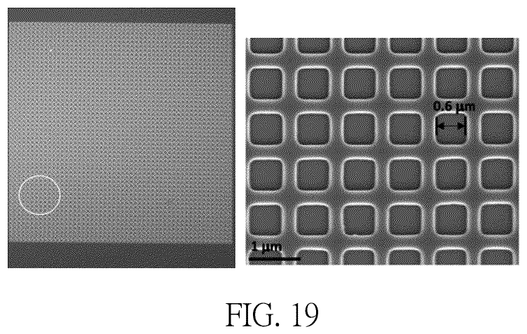

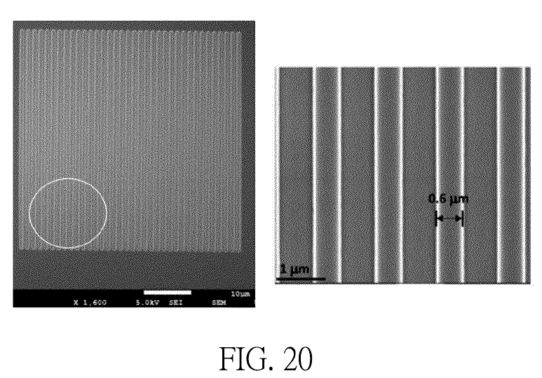

FIGS. 19 and 20 are scanning electron microscope images each showing a patterned sacrificial layer that includes multiple sacrificial structures according to one embodiment of the present disclosure. In FIG. 19, the sacrificial structures form a nano-hole array with a predetermined pitch, a width of each nano-hole can be about 0.6 μm, and a thickness of a sacrificial film formed after the thermal reflow process can be adjusted by controlling the predetermined pitch. For example, a definition of the pitch can be the width plus a gap between two nano-pillars. In FIG. 20, the sacrificial structures form a grating with a predetermined pitch, a width of each nano-wall in the grating can be about 0.6 μm, and a thickness of a sacrificial film formed after the thermal reflow process can be adjusted by controlling the predetermined pitch.

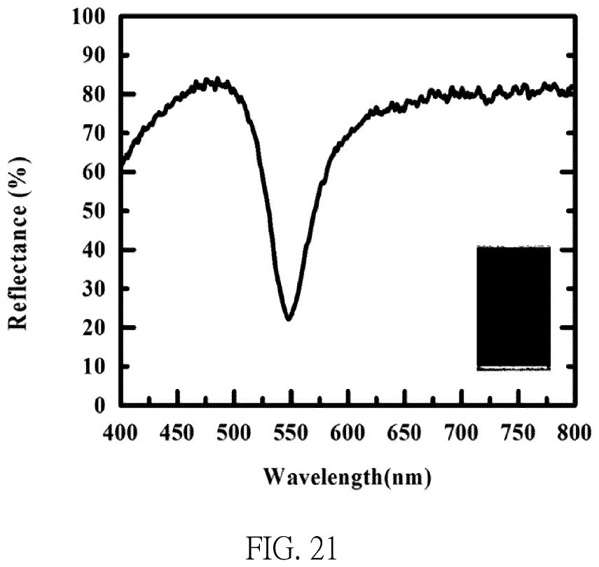

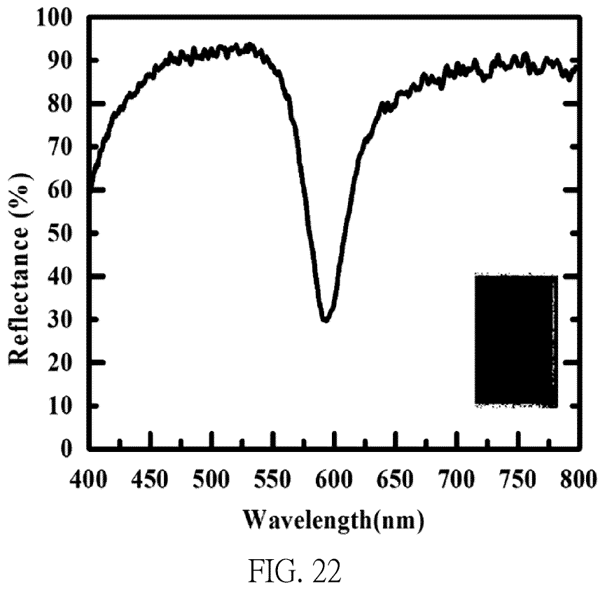

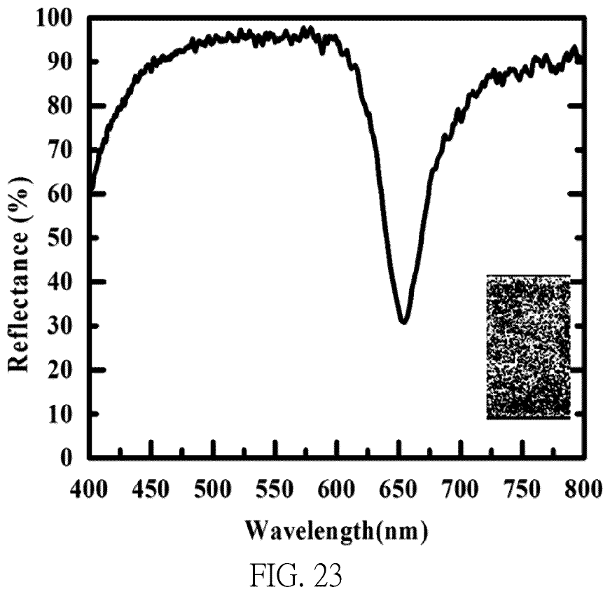

FIGS. 21 to 23 show reflectance spectral of the multi-spectral optical filter with three channels fabricated by using the method of the present disclosure. As shown, the multi-spectral optical filter with a spectral resolution of <30 nm (FWHM) and peak transmission efficiency of ~30% respectively at 550 nm, 600 nm and 650 nm. The angle dependency of the multi-spectral optical filter is further tested, in which the insensitivity can be within half angle of 20 degrees or better.

### Beneficial Effects of the Embodiments

In conclusion, in the multi-spectral optical filter and the method for fabricating the same provided by the present disclosure, the multi-spectral optical filter having multiple channels can be fabricated by precisely controlling the thicknesses of the optical films. The method provided by the present disclosure is CMOS compatible and capable of avoiding multiple coating processes to be performed for each channel, while achieving multiple spectra through the BLR process followed by transferring patterns onto the dielectric layer.

Compared with the existing processes, the multi-spectral optical filter 1 and the method for fabricating the same provided by the present disclosure is more robust as well as reducing the complexity of the manufacturing process, allowing the number of mask steps to be substantially reduced.

Furthermore, for the multi-spectral optical filter with the mask layer, the mask layer located between two different F-P cavity structures can be used to prevent cross-talk issues.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for fabricating a multi-spectral optical filter, the method
comprising the following processes:
providing a substrate;
disposing a first reflection layer on the substrate;
disposing a mask layer on the first reflection layer, wherein the mask layer exposes a first portion and a second portion an upper surface of the first reflection layer, respectively;
disposing an inorganic layer on the mask layer;
disposing a sacrificial layer on the inorganic layer;
patterning the sacrificial layer to form a plurality of first sacrificial structures corresponding to the first portion and a plurality of second sacrificial structures corresponding to the second portion;
reflowing the patterned sacrificial layer to form a stepped sacrificial layer, wherein the stepped sacrificial layer includes a first sacrificial film formed by the plurality of first sacrificial structures and a second sacrificial film formed by the plurality of second sacrificial structures;
performing a pattern transferring process on the stepped sacrificial layer and the inorganic layer to form a stepped inorganic layer, wherein the stepped inorganic layer includes a first optical film corresponding to the first portion and a second optical film corresponding to the second portion; and
disposing a second reflection layer on the stepped inorganic layer.

2. The method according to claim 1, further comprising:
performing a removing process to remove the mask layer and a part of the inorganic layer before disposing the sacrificial layer on the inorganic layer, wherein a first recess portion is formed in the inorganic layer to expose a third portion of the upper surface between the first portion and the second portion after the mask layer is removed.

3. The method according to claim 2, wherein in the process of disposing the sacrificial layer, a first protrusion portion, a second protrusion portion and a second recess portion are formed in the sacrificial layer by filling the first recess portion;
wherein in the process of patterning the sacrificial layer, the plurality of first sacrificial structures are formed in the first protrusion portion, and the plurality of second sacrificial structures are formed in the second protrusion portion; and
wherein the plurality of first sacrificial structures are separately arranged by a first pitch or a first hole width, and the plurality of second sacrificial structures are separately arranged by a second pitch or a second hole width.

4. The method according to claim 3, wherein the first pitch is different from the second pitch, such that thicknesses of the first sacrificial film and the second sacrificial film are different from each other, and thicknesses of the first optical film and the second optical film are different from each other.

5. The method according to claim 1, wherein in the process of disposing the second reflection layer, the second reflection layer includes a first reflection film, a second reflection film and a third reflection film respectively corresponding to the first portion, the second portion and the third portion of the upper surface of the first reflection layer, and heights of the first reflection film, the second reflection film and the third reflection film are different from one another.

6. The method according to claim 1, wherein, in the process of disposing the inorganic layer, the inorganic layer includes a first protrusion portion, a first recess portion and a second recess portion, the first protrusion portion is formed on the mask layer that is corresponding to a third portion of the upper surface between the first portion and the second portion, and the first recess portion and the second recess portion are formed on the first portion and the second portion of the upper surface of the first reflection layer.

7. The method according to claim 6, wherein in the process of disposing the sacrificial layer, a second protrusion portion, a third recess portion and a fourth recess portion are formed in the sacrificial layer, and
wherein in the process of patterning the sacrificial layer, the plurality of first sacrificial structures are formed in the third recess portion, and the plurality of second sacrificial structures are formed in the fourth recess portion;
wherein the plurality of first sacrificial structures are separately arranged by a first pitch, and the plurality of second sacrificial structures are separately arranged by a second pitch, and the first pitch is different from the second pitch.

8. The method according to claim 7, wherein in the process of patterning the sacrificial layer, a first non-patterned portion is formed to surround the plurality of first sacrificial structures, and a second non-patterned portion is formed to surround the plurality of second sacrificial structures;
wherein in the process of reflowing the patterned sacrificial layer to form the stepped sacrificial layer, the stepped sacrificial layer further includes a first boundary formed by the first non-patterned portion and a second boundary formed by the second non-patterned portion, a thickness of the first boundary is larger than the thickness of the first sacrificial film, and a thickness of the second boundary is larger than the thickness of the second sacrificial film.

9. The method according to claim 8, wherein in the pattern transferring process, the stepped inorganic layer further includes a third boundary surrounding the first optical film and a fourth boundary surrounding the second optical film.

10. The method according to claim 1, further comprising:
disposing a packaging layer on the second reflection layer.

11. A multi-spectral optical filter, comprising:
a substrate;
a first reflection layer disposed on the substrate;
a stepped inorganic layer disposed on the first reflection layer, wherein the stepped inorganic layer includes a first optical film and a second optical film corresponding to a first portion and a second portion of an upper surface of the first reflection layer, respectively;
a second reflection layer disposed on the stepped inorganic layer; and
a spacing structure formed on a third portion of the upper surface of the first reflection layer, wherein the third portion is located between the first portion and the second portion;
wherein thicknesses of the first optical film and the second optical film are different from each other.

12. The multi-spectral optical filter according to claim 11, further comprising a packaging layer disposed on the second reflection layer.

13. The multi-spectral optical filter according to claim 12, wherein the packaging layer and the stepped inorganic layer are made of identical materials.

14. The multi-spectral optical filter according to claim 11, wherein the second reflection layer includes a first reflection film a second reflection film respectively corresponding to the first portion and the second portion of the upper surface of the first reflection, and heights of the first reflection film and the second reflection film are different from one another.

15. The multi-spectral optical filter according to claim 14, further comprising an opaque component disposed on the third portion of the upper surface of the first reflection layer, wherein the spacing structure is formed by one or more of the opaque component, the stepped inorganic layer and the second reflection layer.

16. The multi-spectral optical filter according to claim 15, wherein the opaque component is formed by a light blocking material or a light reflecting material.

17. The multi-spectral optical filter according to claim 14, wherein the stepped inorganic layer further includes a first boundary surrounding the first optical film and a second boundary surrounding the second optical film, a height of a top of the first and second boundary is larger than a height of a top of the first optical film and the second optical film.

18. The multi-spectral optical filter according to claim 17, wherein the second reflection layer further includes a third reflection film layer corresponding to the third portion of an upper surface of the first reflection layer, the first reflection film layer is disposed on the first optical film and surrounded by the first boundary, the second reflection film layer is disposed on the second optical film and surrounded by the second boundary, the third reflection film layer is surrounded by the first boundary and the second boundary as a part of the spacing structure, and heights of the first reflection film layer, the second reflection film layer and the third reflection film layer are different from one another.

19. The multi-spectral optical filter according to claim 15, wherein a height of the spacing structure is different to heights of the first reflection film layer, the second reflection film layer.

20. The multi-spectral optical filter according to claim 19, wherein the second reflection layer further includes a third reflection film layer corresponding to the third portion of an upper surface of the first reflection layer, the third reflection film layer is disposed on a protrusion portion or a recess portion of the stepped inorganic layer as a part of the spacing structure.
